(19) United States
(12) Patent Application Publication
(10) Pub. No.: US 2007/0015356 A1
(43) Pub. Date: Jan. 18, 2007

(54) Method for forming contact hole in semiconductor device

(76) Inventors: Min-Suk Lee, Kyoungki-do (KR); Sung-Kwon Lee, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/361,525

(22) Filed: Feb. 24, 2006

(30) Foreign Application Priority Data
Jun. 24, 2005 (KR) 2005-0054893

(51) Int. Cl. H01L 21/4763

(52) U.S. Cl. 438/637

(57) ABSTRACT

A method for forming a contact hole in a semiconductor device is provided. A method for forming a contact hole in a semiconductor device includes: forming an insulation layer over a bottom structure; forming a hard mask pattern over the insulation layer; etching a portion of the insulation layer using the hard mask pattern as an etch mask to form an opening; forming spacers over sidewalls of the hard mask pattern and the insulation layer patterned by the etching; etching a remaining portion of the insulation layer to form a contact hole exposing a portion of the bottom structure; and removing the spacers and the hard mask pattern.

### FIELD OF THE INVENTION

The present invention relates to a method for fabricating a semiconductor device; and, more particularly, to a method for forming a contact hole in a semiconductor device.

### DESCRIPTION OF RELATED ART

Generally, a semiconductor device includes numerous unit devices. As semiconductor devices have become more highly integrated, these unit devices have to be formed densely within a limited cell area. As a result, unit devices such as transistors and capacitors have been scaled down. Especially, as the design rule in semiconductor memory devices such as dynamic random access memories (DRAMs) has been shifted towards minimization, sizes of the unit devices formed within the cell area have decreased; however, aspect ratios thereof have to be increased to secure a sufficient level of capacitance.

One representative example of the increasing aspect ratio is a process of forming deep contact holes for metal lines in a peripheral region after bit lines and capacitors are formed in a cell region. If capacitors are formed in a concave structure, the thickness of an etch target for forming metal contacts increases, resulting in an incidence that contact holes are not opened or are opened improperly.

When a photolithography process using argon fluoride (ArF) having a wavelength of 193 nm as a light source is used in connection with sub-80 nm level semiconductor devices, a condition to prevent deformation of a photoresist pattern which might occur during an etching process may be required in addition to the known etch conditions, for instance, the conditions for forming patterns precisely or vertical etch profiles. Thus, for fabrication of such sub-80 nm level semiconductor devices, many researchers have focused on developing a process condition that concurrently satisfies the known etch conditions and the additional condition for preventing the photoresist deformation.

A current trend of the decreasing design rule due to large scale integration makes it possible to realize a structure of multiple metal lines. However, contact holes are formed close to each other since a height difference between device elements increases due to the large scale of integration and the design rule applied to a peripheral region is nearly identical to that applied to a cell region in order to increase cell efficiency. Hence, a bowing incidence frequently occurs during an etching process for forming deep contact holes for metal lines, and the bowing incidence causes a generation of defects in devices.

FIG. 1 is a cross-sectional view illustrating a conventional method for forming a contact hole in a semiconductor device.

As illustrated, a multi-level insulation layer 12 is formed on a substrate 11 in which device isolation regions, word lines, bit lines and other elements necessary for the configuration of a DRAM are formed. The multi-level insulation layer 12 is formed of borosilicate glass (BSG), borophosphosilicate glass (BPSG), phosphosilicate glass (PSG), tetraethyl orthosilicate (TEOS), high density plasma (HDP) oxide, spin on glass (SOG), or advanced planarization layer (APL). In addition to these oxide-based materials, an organic or inorganic low-K dielectric material can be used for the multi-level insulation layer 12.

Although not illustrated, a hard mask pattern is formed on the multi-level insulation layer 12, which is subsequently etched using the hard mask pattern as an etch mask, so that deep contact holes 13 exposing portions of the substrate 11 designated for contact regions are formed. During this etching process, etching ions over etch upper portions of the multi-level insulation layer 12, and thus, a bowing incidence occurs in lateral sides of the contact holes 13. Reference denotation ‘A’ in FIG. 1 represents the bowing incidence.

In detail of the bowing incidence, due to large scale integration, the depth of a contact hole increases, and the width of the contact hole decreases, and an etch target increases. Thus, etching ions over etch upper portions of an insulation layer, and this over etching often results in a bowing incidence in the contact hole. The bowing incidence which often occurs between adjacently disposed contact holes may be disadvantageous.

### SUMMARY OF THE INVENTION

It is, therefore, an object of the present invention to provide a method for forming a contact hole in a semiconductor device, wherein the method can reduce an occurrence of a bowing incidence to thereby improve a gap-fill margin of a conductive layer for forming a plug and a product yield of devices.

In accordance with an aspect of the present invention, there is provided a method for forming a contact hole in a semiconductor device including: forming an insulation layer over a bottom structure; forming a hard mask pattern over the insulation layer; etching a portion of the insulation layer using the hard mask pattern as an etch mask to form an opening; forming spacers over sidewalls of the hard mask pattern and the insulation layer patterned by the etching; etching a remaining portion of the insulation layer to form a contact hole exposing a portion of the bottom structure; and removing the spacers and the hard mask pattern.

In accordance with another aspect of the present invention, there is provided a method for forming a contact hole in a semiconductor device including: sequentially forming first to third insulation layers over a bottom structure; forming a hard mask pattern over the third insulation layer; etching the third insulation layer using the hard mask pattern as an etch mask to form an opening; forming spacers over sidewalls of the hard mask pattern and the third insulation layer patterned by the etching; etching the second insulation layer and the first insulation layer to form a contact hole exposing a portion of the bottom structure; and removing the spacers and the hard mask pattern.

### BRIEF DESCRIPTION OF THE DRAWINGS

The above and other objects and features of the present invention will become better understood with respect to the following description of the preferred embodiments given in conjunction with the accompanying drawings, in which:

FIG. 1 is a cross-sectional view illustrating a conventional method for forming a contact hole in a semiconductor device; and

FIGS. 2A to 2E are cross-sectional views illustrating a method for forming a contact hole in a semiconductor device in accordance with an embodiment of the present invention.

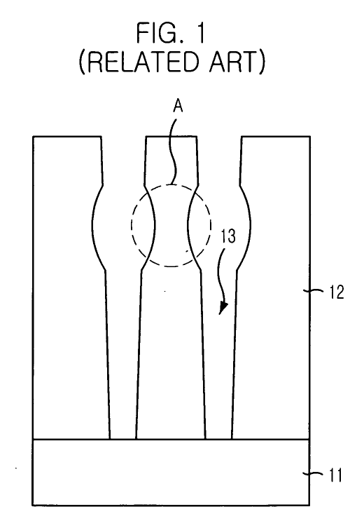

### DETAILED DESCRIPTION OF THE INVENTION

A method for forming a contact hole in a semiconductor device in accordance with exemplary embodiments of the present invention will be described in detail with reference to the accompanying drawings.

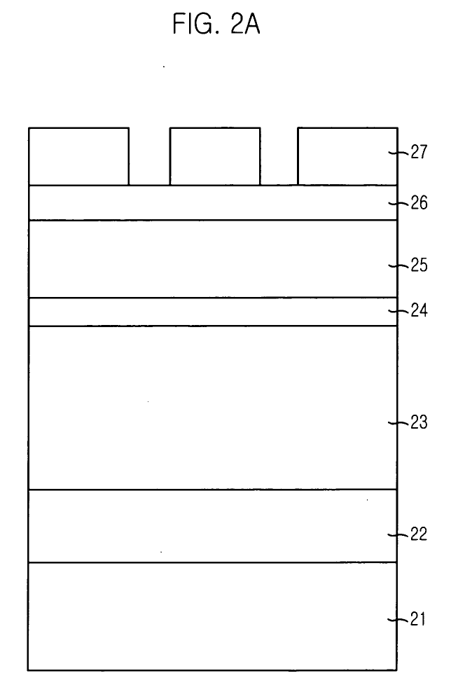

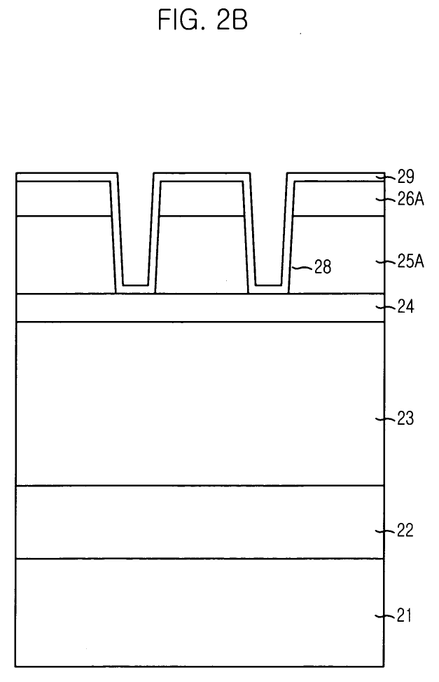

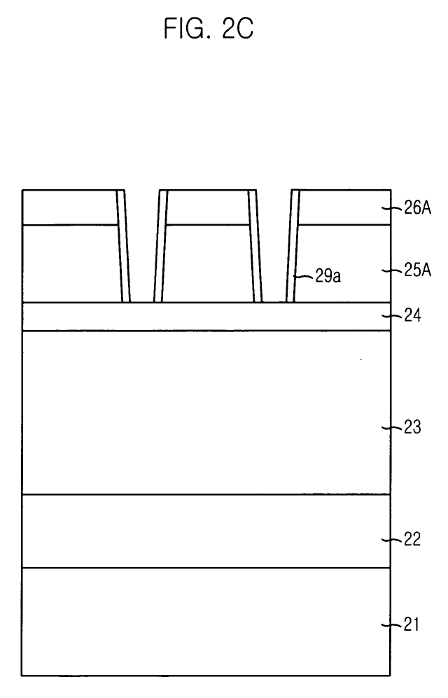

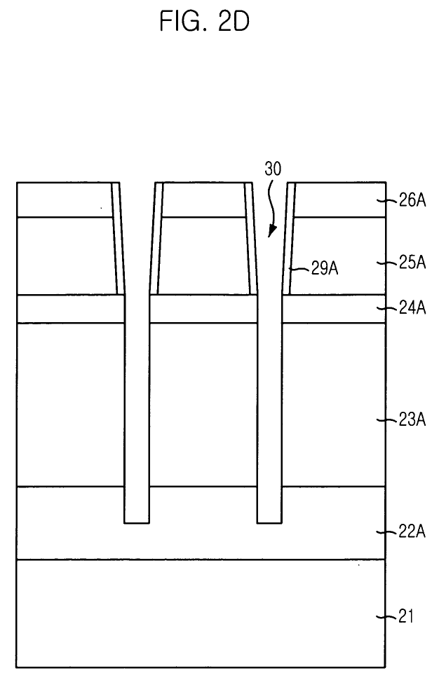

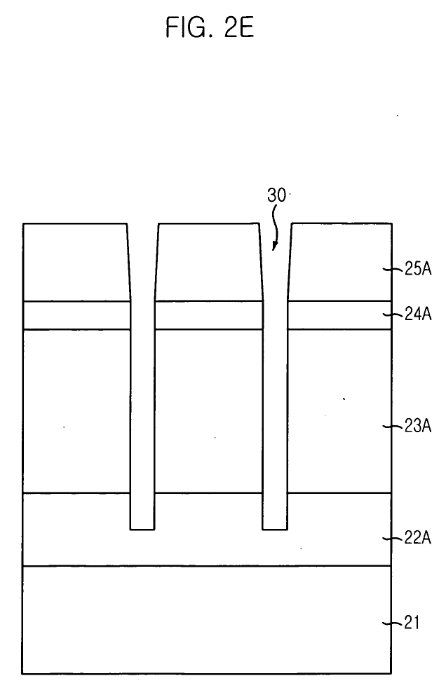

FIGS. 2A to 2E are cross-sectional views illustrating a method for forming a contact hole in a semiconductor device in accordance with an embodiment of the present invention.

Referring to FIG. 2A, a bottom structure 22 necessary for configuring word lines, bit lines and other elements for a dynamic random access memory (DRAM) is formed on a substrate 21 in which device isolation regions are formed. The bottom structure 22 can include a conductive layer, which may be used for forming plugs. First to third inter-layer insulation layers 23, 24 and 25 are formed on the bottom structure 22. The first inter-layer insulation layer 23 and the third inter-layer insulation layer 25 include one selected from the group consisting of an oxide-based material, a nitride-based material, a low-K dielectric material and a combination thereof. The oxide-based material is selected from the group consisting of borosilicate glass (BSG), borophosphosilicate glass (BPSG), phosphosilicate glass (PSG), tetraethyl orthosilicate (TEOS), plasma enhanced tetraethyl orthosilicate (PETEOS), low pressure tetraethyl orthosilicate (LPTEOS), high density plasma (HDP) oxide, spin on glass (SOG), and advanced planarization layer (APL). The nitride-based material includes plasma enhanced nitride or plasma enhanced oxynitride. The low-K dielectric material may be an organic or inorganic low-K dielectric material. Also, the first inter-layer insulation layer 23 and the third inter-layer insulation layer 25 are formed to a thickness ranging from approximately 2,000 Å to approximately 15,000 Å. The second inter-layer insulation layer 24 includes an insulation material such as undoped polysilicon, aluminum oxide, aluminum nitride, or tantalum oxide and serves as an etch stop layer. Also, the second inter-layer insulation layer 24 is formed to a thickness of approximately 50 Å to approximately 500 Å. Thus, the total thickness of the first to third inter-layer insulation layers range from approximately 8,000 Å to approximately 30,000 Å.

A hard mask layer 26 and a photoresist pattern 27 are sequentially formed on the third inter-layer insulation layer 25. The hard mask layer 26 includes one selected from the group consisting of tungsten, amorphous carbon, polysilicon, and an organic polymer based material such as siLK or a silicon contained polymer, and in the present embodiment, the hard mask layer 26 includes amorphous carbon and is formed to a thickness of approximately 2,000 Å to approximately 10,000 Å.

Referring to FIG. 2B, the hard mask layer 26 is etched using the photoresist pattern as an etch mask to form a hard mask pattern 26A. The photoresist pattern 27 is stripped, and a cleaning process is performed to remove etch remnants thereafter.

Using the hard mask pattern 26A as an etch mask, portions of the third inter-layer insulation layer 25 where a bowing incidence typically occurs are etched to form openings 28. At this point, the etched thickness of the third inter-layer insulation layer 25 ranges from approximately 3,000 Å to approximately 12,000 Å. The openings 28 expose predetermined portions of the second inter-layer insulation layer 24 for the purpose of etching portions of the multiple insulation layers prone to a bowing incidence when an etching process for forming subsequent deep contact holes is performed and for providing uniformity of an insulation layer, which is subsequently etched for forming spacers. Reference numeral 25A denotes a patterned third inter-layer insulation layer.

A thin layer 29 for forming a spacer is formed over the above resultant structure obtained after the selective etching of the third inter-layer insulation layer 25. The thin layer 29 includes silicon nitride (SiN) or silicon oxynitride (SiON) and is formed to a thickness of approximately 50 Å to approximately 500 Å.

Referring to FIG. 2C, an etch-back process is performed to selectively remove portions of the thin layer 29 disposed over the hard mask pattern 26A and at the bottom of the openings 28. After the etch-back process, spacers 29A are formed over sidewalls of the hard mask pattern 26A and the patterned third inter-layer insulation layer 25A. The spacers 29A protect portions where the bowing incidence frequently occurs to thereby minimize an occurrence of the bowing incidence. As a result, an effective conductivity level between a subsequent conductive material and the bottom structure 22 can be achieved.

Referring to FIG. 2D, the second inter-layer insulation layer 24, the first inter-layer insulation layer 23 and the bottom structure 22 are sequentially etched using the hard mask pattern 26A as an etch mask along with an etch gas that etches an insulation material. This etching process continues until the conductive layer of the bottom structure 22 is exposed, and from this etching process, deep openings 30 are formed. Reference numerals 24A, 23A and 22A represent a patterned second inter-layer insulation layer, a patterned first inter-layer insulation layer and a patterned bottom structure, respectively.

Referring to FIG. 2E, the hard mask pattern 26A and the spacers 29A are removed. At this time, the hard mask pattern 26A has a wet etch selectivity with respect to the patterned second inter-layer insulation layer 24A. For instance, if the patterned second inter-layer insulation layer 24A includes polysilicon, the hard mask pattern 26A includes amorphous carbon or tungsten.

According to the present embodiment of the present invention, spacers are formed in regions where a bowing incidence frequently occurs, and deep contact holes are formed using the spacers as an etch mask. Particularly, the spacers make it possible to form the deep contact holes without generating a bowing incidence. As a result, a gap-fill margin of a conductive material for forming a plug and a short margin between adjacent contact holes can be improved, and accordingly, a product yield of semiconductor devices can be enhanced.

The present application contains subject matter related to the Korean patent application No. KR 2005-54893, filed in the Korean Patent Office on Jun. 24, 2005, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A method for forming a contact hole in a semiconductor device comprising:
forming an insulation layer over a bottom structure;
forming a hard mask pattern over the insulation layer;
etching a portion of the insulation layer using the hard mask pattern as an etch mask to form an opening;
forming spacers over sidewalls of the hard mask pattern and the insulation layer patterned by the etching;
etching a remaining portion of the insulation layer to form a contact hole exposing a portion of the bottom structure; and
removing the spacers and the hard mask pattern.

2. The method of claim 1, wherein the forming of the insulation layer over the bottom structure comprises forming an etch stop layer over the bottom structure.

3. The method of claim 1, wherein the forming of the insulation layer comprises using one selected from the group consisting of an oxide-based material, a nitride-based material, a low-K dielectric material, and a combination thereof.

4. The method of claim 3, wherein the oxide-based material is selected from the group consisting of phosphosilicate glass, borosilicate glass, borophosphosilicate glass, plasma enhanced tetraethyl orthosilicate, low pressure tetraethyl orthosilicate, and high density plasma oxide.

5. The method of claim 3, wherein the nitride-based material includes at least one of plasma enhanced nitride and plasma enhanced oxynitride.

6. The method of claim 1, wherein the insulation layer has a thickness ranging from approximately 8,000 Å to approximately 30,000 Å.

7. The method of claim 1, wherein the bottom structure includes a conductive layer.

8. The method of claim 2, wherein the etch stop layer includes one selected from the group consisting of undoped polysilicon, aluminum oxide, aluminum nitride, and tantalum oxide.

9. The method of claim 8, wherein the etch stop layer is formed to a thickness ranging from approximately 50 Å to approximately 500 Å.

10. The method of claim 1, wherein the spacers include at least one of silicon nitride and silicon oxynitride.

11. The method of claim 1, wherein the spacers are formed to a thickness ranging from approximately 50 Å to approximately 500 Å.

12. The method of claim 1, wherein the etching of the portion of the insulation layer to form the opening comprises etching approximately 3,000 Å to approximately 12,000 Å of the insulation layer.

13. The method of claim 1, wherein the hard mask pattern includes one selected from the group consisting of amorphous carbon, tungsten, and an organic polymer based material.

14. The method of claim 9, wherein the organic polymer based material includes at least one of SILK and a silicon based polymer.

15. A method for forming a contact hole in a semiconductor device comprising:
sequentially forming first to third insulation layers over a bottom structure;
forming a hard mask pattern over the third insulation layer;
etching the third insulation layer using the hard mask pattern as an etch mask to form an opening;
forming spacers over sidewalls of the hard mask pattern and the third insulation layer patterned by the etching;
etching the second insulation layer and the first insulation layer to form a contact hole exposing a portion of the bottom structure; and
removing the spacers and the hard mask pattern.

16. The method of claim 15, wherein the first to third insulation layers have a total thickness ranging from approximately 8,000 Å to approximately 30,000 Å.

17. The method of claim 15, wherein the bottom structure includes a conductive layer.

18. The method of claim 15, wherein the sequential forming of the first to third insulation layers comprises forming the second insulation layer serving as an etch stop layer to a thickness ranging from approximately 50 Å to approximately 500 Å.

19. The method of claim 18, wherein the etch stop layer includes one selected from the group consisting of undoped polysilicon, aluminum oxide, aluminum nitride, and tantalum oxide.

20. The method of claim 15, wherein the spacers include at least one of silicon nitride and silicon oxynitride.
